(19) United States
(12) Patent Application Publication
(10) Pub. No.: US 2014/0091272 A1
(43) Pub. Date: Apr. 3, 2014

(54) RESISTANCE VARIABLE MEMORY STRUCTURE AND METHOD OF FORMING THE SAME

(71) Applicant: TAIWAN SEMICONDUCTOR MANUFACTURING COMPANY, L, Hsinchu (TW)

(72) Inventors: Yu-Wen LIAO, New Taipei City (TW); Wen-Ting CHU, Kaohsiung City (TW); Chin-Chieh YANG, New Taipei City (TW); Kuo-Chi TU, Hsinchu (TW); Chih-Yang CHANG, Yuanlin Township (TW); Hsia-Wei CHEN, Taipei City (TW)

(73) Assignee: TAIWAN SEMICONDUCTOR MANUFACTURING COMPANY, LTD., Hsinchu (TW)

(21) Appl. No.: 13/630,387

(22) Filed: Sep. 28, 2012

(51) Int. Cl. H01L 45/00

(52) U.S. Cl. 257/4; 438/382; 257/E45.003

(57) ABSTRACT

A semiconductor structure includes a resistance variable memory structure. The semiconductor structure also includes a conductive structure. The resistance variable memory structure is over the conductive structure. The resistance variable memory structure includes a first electrode over the conductive structure. A resistance variable layer is disposed over the first electrode. A cap layer is disposed over the resistance variable layer. The cap layer includes a first metal material. A second electrode disposed over the cap layer. The second electrode includes a second metal material different from the first metal material.

### TECHNICAL FIELD

This disclosure relates generally to a semiconductor structure and, more particularly, to a resistance variable memory structure and method for forming a resistance variable memory structure.

### BACKGROUND

In integrated circuit (IC) devices, resistive random access memory (RRAM) is an emerging technology for next generation non-volatile memory devices. An RRAM is a memory structure including an array of RRAM cells each of which stores a bit of data using resistance values, rather than electronic charge. Particularly, each RRAM cell includes a resistance variable layer, the resistance of which can be adjusted to represent logic “0” or logic “1”.

From an application point of view, the RRAM has many advantages. The RRAM has a simple cell structure and CMOS logic comparable processes which results in a reduction of the manufacturing complexity and cost in comparison with other non-volatile memory structures. Despite the attractive properties noted above, a number of challenges exist in connection with developing the RRAM. Various techniques directed at configurations and materials of these RRAMs have been implemented to try and further improve device performance.

### BRIEF DESCRIPTION OF THE DRAWINGS

Aspects of the present disclosure may be understood from the following detailed description and the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method of forming a semiconductor structure having a resistance variable memory structure according to one or more embodiments of this disclosure.

FIGS. 2A to 2E are cross-sectional views of semiconductor structures having a resistance variable memory structure at various stages of manufacture according to one or more embodiments of the method of FIG. 1.

FIG. 3 illustrates a cross-sectional view of a resistance variable memory structure in operation with filaments formed in a resistance variable layer of the resistance variable memory structure according to at least one embodiment of this disclosure.

FIG. 4 is a cross-sectional view of a semiconductor structure having a resistance variable memory structure according to at least one embodiment of the method of FIG. 1.

FIG. 5 is a schematic diagram for a memory array having resistance variable memory structures according to at least one embodiment of this disclosure.

### DETAILED DESCRIPTION

The making and using of illustrative embodiments are discussed in detail below. It should be appreciated, however, that the disclosure provides many applicable inventive concepts that can be embodied in a wide variety of specific contexts. The specific embodiments discussed are merely illustrative and do not limit the scope of the disclosure.

According to one or more embodiments of this disclosure, a semiconductor structure includes a resistance variable memory structure. The resistance variable memory structure includes a resistance variable layer formed between two electrodes. By applying a specific voltage to each of the two electrodes, an electric resistance of the resistance variable layer is altered. The low and high resistances are utilized to indicate a digital signal “1” or “0”, thereby allowing for data storage.

According to one or more embodiments of this disclosure, the semiconductor structure having a resistance variable memory structure is formed within a chip region of a substrate. A plurality of semiconductor chip regions is marked on the substrate by scribe lines between the chip regions. The substrate will go through a variety of cleaning, layering, patterning, etching and doping steps to form the semiconductor structures. The term “substrate” herein generally includes a bulk substrate on which various layers and device structures are formed. In some embodiments, the bulk substrate includes silicon or a compound semiconductor, such as GaAs, InP, Si/Ge, or SiC. Examples of such layers include dielectric layers, doped layers, polysilicon layers or conductive layers. Examples of device structures include transistors, resistors, and/or capacitors, which may be interconnected through an interconnect layer to additional integrated circuits.

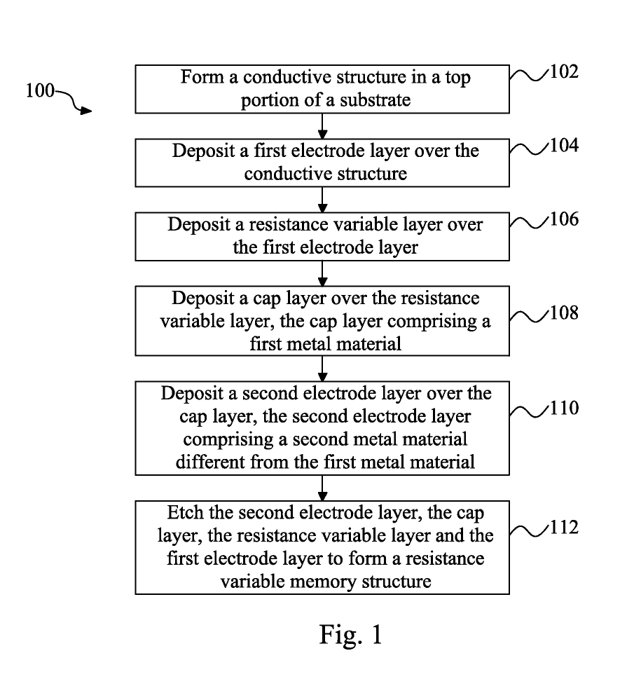

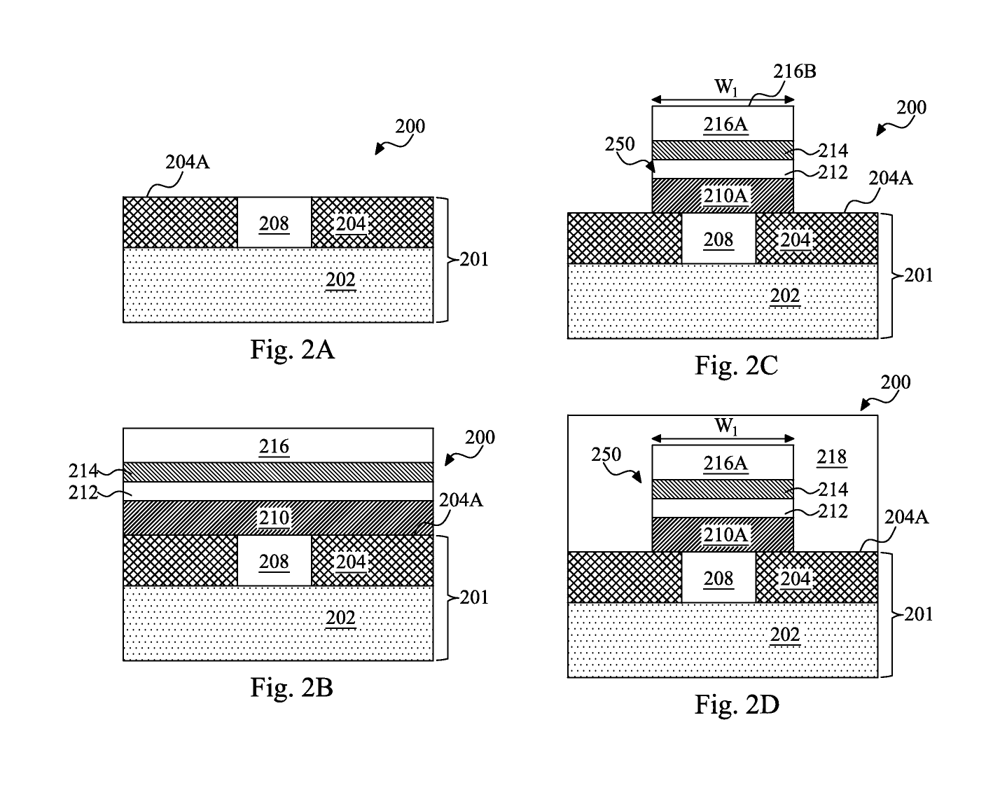

FIG. 1 is a flowchart of a method 100 of forming a semiconductor structure having a resistance variable memory structure according to one or more embodiments of this disclosure. FIGS. 2A to 2E are cross-sectional views of a semiconductor structure 200 having a resistance variable memory structure at various stages of manufacture according to various embodiments of the method 100 of FIG. 1. It should be noted that additional processes may be provided before, during, or after the method 100 of FIG. 1. Various figures have been simplified for a better understanding of the inventive concepts of the present disclosure.

Referring back to FIG. 1, the flowchart of the method 100 begins with operation 102. A conductive structure is formed in a top portion of a substrate. The substrate may include various layers on the top portion of the substrate. In at least one embodiment, the conductive structure is formed in a dielectric layer on the top portion of the substrate.

FIG. 2A is an enlarged cross-sectional view of a portion of a semiconductor structure 200 having a resistance variable memory structure after performing operation 102. The semiconductor structure 200 includes a substrate 201. The substrate 201 includes a bulk substrate 202 such as a silicon carbide (SiC) substrate, GaAs, InP, Si/Ge or a silicon substrate. According to one or more embodiments, the substrate 201 includes a plurality of layers formed on a top portion of the substrate 201. Examples of such layers include dielectric layers, doped layers, polysilicon layers or conductive layers. According to one or more embodiments, the substrate 201 further includes a plurality of device structures (not shown) formed within plurality of layers. Examples of device structures include transistors, resistors, and/or capacitors.

In the illustrated examples of FIGS. 2A-2E, the semiconductor structure 200 includes a conductive structure 208 formed in a dielectric layer 204 on the top portion of the substrate 201. The dielectric layer 204 may comprise silicon oxide, fluorinated silica glass (FSG), carbon doped silicon oxide, silicon nitride, silicon oxynitride, TEOS oxide, phosphosilicate glass (PSG), borophosphosilicate glass (BPSG), Black Diamond® (Applied Materials of Santa Clara, Calif.), amorphous fluorinated carbon, low-k dielectric material, or combinations thereof. The deposition process may include chemical vapor deposition (CVD), atomic layer deposition (ALD), high density plasma CVD (HDPCVD) or spinning on glass.

According to one or more embodiments, the conductive structure 208 includes a conductive interconnect, a doped region or a silicide region. In some embodiments, the conductive structure 208 includes Al, Cu, Ti, Ta, W, Mo, TaN, NiSi, CoSi, TiN, WN or silicon. The conductive structure 208 is formed by suitable processes, including deposition, lithography patterning, doping, implanting, etching processes, chemical mechanical polishing (CMP) or planarization etching back process.

Referring back to FIG. 1, method 100 continues with operations 104 to 110. In operation 104, a first electrode layer is formed over the conductive structure. In operation 106, a resistance variable layer is deposited over the first electrode layer. In operation 108, a cap layer is deposited over the resistance variable layer. The cap layer includes a first metal material. In operation 110, a second electrode layer is deposited over the cap layer. The second electrode layer includes a second metal material different from the first metal material.

FIG. 2B illustrates a cross-sectional view of the semiconductor structure 200 after performing operations 104 to 110. A first electrode layer 210 is formed overlying the conductive structure 208 and on a top surface 204A of the dielectric layer 204. The conductive structure 208 may electrically connect the first electrode layer 204 to underlying device structures in the substrate 201. The first electrode layer 210 includes a conductive material having a proper work function such that a high work function wall is built between the first electrode layer 210 and a resistance variable layer subsequently formed. The first electrode layer 210 may comprise at least one of platinum, aluminum copper, titanium nitride, gold, titanium, tantalum, tantalum nitride, tungsten, tungsten nitride or copper. The possible formation methods include electroless plating, sputtering, electro plating, PVD or ALD.

A resistance variable layer 212 is deposited over the first electrode layer 210. The resistance variable layer 212 has a resistivity capable of switching between a high resistance state and a low resistance state (or conductive), by application of an electrical voltage. In various embodiments, the resistance variable layer 212 includes dielectric materials comprising at least one of a high-k dielectric material, a binary metal oxide or a transition metal oxide. In some embodiments, the resistance variable layer 212 includes at least one of nickel oxide, titanium oxide, hafnium oxide, zirconium oxide, zinc oxide, tungsten oxide, aluminum oxide, tantalum oxide, molybdenum oxide or copper oxide. The possible formation methods include PVD or ALD, such as ALD with a precursor containing zirconium and oxygen. In one or more embodiments, the resistance variable layer 212 has a thickness in a range from about 20 angstrom to about 200 angstrom.

A cap layer 214 is formed on the resistance variable layer 212. The cap layer 214 includes a first metal material that is unstable, capable of depriving oxygen from the resistance variable layer 212, or creates vacancy defects in the resistance variable layer 212. The cap layer 214 comprises at least one of titanium, platinum or palladium.

A second electrode layer 216 is deposited over the cap layer 214. The second electrode layer 216 may include a second metal material to electrically connect a later formed resistance variable memory structure (e.g., structure 250 as shown in FIG. 2C) to a portion of an interconnect structure for electrical routing. The switching behavior of the resistance variable memory structure does not depend only on the materials of the resistance variable layer but also depends on the choice of electrodes and the corresponding interfacial properties of the electrodes.

In some examples, the same metal material may be used in both second electrode layer 216 and cap layer 214. Due to the same metal material in both second electrode layer 216 and cap layer 214, the layers 216 and 214 may intermix. Some other materials in second electrode layer 216 may penetrate through an interface to the cap layer 214. As a result, the first metal material in the cap layer 214 is possibly contaminated and may have less capability to deprive oxygen from the resistance variable layer 212, or create vacancy defects in the resistance variable layer 212. A high electrical voltage is needed to generate a conduction portion in the resistance variable layer 212 for the switching behavior of the resistance variable memory structure. The operation mechanism of the resistance variable memory structure will be introduced later in this specification.

In this disclosure, according to one or more embodiments, the second metal material in the second electrode layer 216 is different from the first metal material in the cap layer 216. This disclosure eliminates the drawbacks of easily intermixing of the second electrode layer 216 and the cap layer 214. Further, the semiconductor structure 200 according to one or more embodiments reduces the operation voltage to generate the conduction portion in the resistance variable layer 212.

According to one or more embodiments, the second electrode material 216 comprises platinum, aluminum copper, titanium nitride, gold, titanium, tantalum, tantalum nitride, tungsten, tungsten nitride or copper. In some embodiments, the conductive material of the first electrode layer 210 and the conductive material of the second electrode layer 216 have a same composition. In certain embodiments, the conductive material of the first electrode layer 210 and the conductive material of the second electrode layer 216 have different compositions. The possible formation methods include electroless plating, sputtering, electro plating, PVD or ALD.

Referring back to FIG. 1, method 100 continues with operation 112. The second electrode layer, the cap layer, the resistance variable layer and the first electrode layer are etched to form a resistance variable memory structure.

FIG. 2C illustrates a cross-sectional view of the semiconductor structure 200 after performing operation 112. In FIG. 2C, a mask layer (not shown) having a feature with a width W₁ is formed over the second electrode layer 216. The feature is formed by a suitable process, including deposition, lithography patterning, and/or etching processes. An etching process is performed to remove the second electrode layer 216, the cap layer 214, the resistance variable layer 212 and the first electrode layer 210 not underlying the feature of the mask layer. Then, a resistance variable memory structure 250 is formed. The resistance variable memory structure 250 includes the patterned second electrode layer 216 (also referred as second electrode 216A), the patterned cap layer 214, the patterned resistance variable layer 212 and the patterned first electrode layer 210 (also referred as first electrode 210A). Since the second electrode layer 216, the cap layer 214, the resistance variable layer 212 and the first electrode layer 210 are covered and etched under the same mask layer, all the patterned layers 210, 212, 214 and 216) have a substantially same width W₁ as the width W₁ of the feature in the mask layer. Also, the second electrode 216A, the patterned cap layer 214, the patterned resistance variable layer 212 and the first electrode 210A have substantially aligned sidewalls.

The mask layer is removed after the etching process for the resistance variable memory structure 250 and a top surface of the second electrode 216B is exposed. The removing process may include a dry etching process, wet etching process, or combination thereof.

It should be noted that additional processes may be provided after the method 100 of FIG. 1. FIG. 2D illustrates a cross-sectional view of the semiconductor structure 200 after forming an inter-level dielectric (ILD) layer 218. The ILD layer 218 may be blanket formed over the resistance variable memory structure 250. A chemical mechanical polishing (CMP) process is further applied to the semiconductor structure 200 to planarize the ILD layer 218. The ILD layer 218 may include multiple dielectric layers. The ILD layer 218 may comprise silicon oxide, fluorinated silica glass (FSG), carbon doped silicon oxide, silicon nitride, silicon oxynitride, TEOS oxide, phosphosilicate glass (PSG), borophosphosilicate glass (BPSG), Black Diamond® (Applied Materials of Santa Clara, Calif.), amorphous fluorinated carbon, low-k dielectric material, or combinations thereof. The deposition process may include chemical vapor deposition (CVD), atomic layer deposition (ALD), high density plasma CVD (HDPCVD) or spinning on glass.

FIG. 2E illustrates a cross-sectional view of the semiconductor structure 200 after forming a contact plug 220 connecting to the resistance variable memory structure 250. An opening is etched in the ILD layer 218 to expose a portion of the top surface 216B of the second electrode 216A. A conductive material of the contact plug 220 may overfill the opening in the ILD layer 218. The conductive material may include copper or copper alloys, aluminum or tungsten. The possible formation methods include electroless plating, sputtering, electro plating or chemical vapor deposition (CVD). The excess conductive material outside of the opening is removed through a suitable process such as chemical mechanical polishing (CMP). The contact plug 220 having the conductive material is formed on the resistance variable memory structure 250 and contacts the second electrode 216A of the resistance variable memory structure 250.

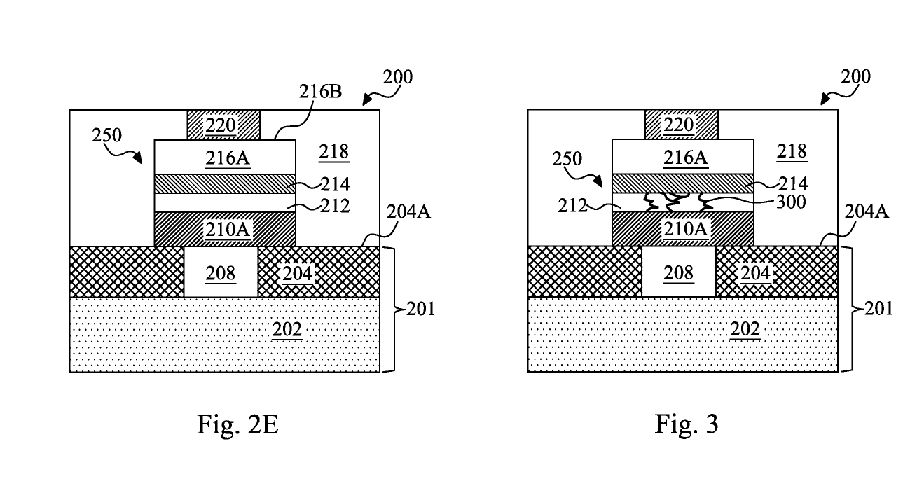

FIG. 3 illustrates an enlarged cross-sectional view of the semiconductor structure 200 having the resistance variable memory structure 250 in FIG. 2E in various operations for data storage. In a “forming” operation, a “forming” voltage is applied to the two electrodes 210A and 216A of the resistance variable memory structure 250. The “forming” voltage is high enough to generate a conductive portion in the resistance variable layer 212. In one example, the conductive portion includes one or more conductive filaments 300 to provide a conductive path such that the resistance variable layer 212 is in an “on” or low resistance state. The conductive path may be related to the lineup of the defect (e.g. oxygen) vacancies in the resistance variable layer 212. In some embodiments, the “forming” voltage is applied only one time. Once the conductive path is formed by the conductive filament 300, it remains in the resistance variable layer 212. Other operations may disconnect or reconnect the conductive path using smaller voltages or different voltages.

In a “set” operation, a “set” voltage is high enough to reconnect the conductive path in the resistance variable layer 212 such that the resistance variable layer 212 is in the “on” or low resistance state. The “set” operation turns the resistance variable layer 212 to the low resistance state.

In a “reset” operation, a “reset” voltage is high enough to break the conductive path in the resistance variable layer 212 such that the resistance variable layer 212 is in an “off” or high resistance state. By applying a specific voltage (i.e., the forming voltage, set voltage or reset voltage) between two electrodes 210A and 216A, an electric resistance of the resistance variable layer 212 is variable after applying the specific voltage. The low and high resistances are utilized to indicate a digital signal “1” or “0”, thereby allowing for data storage.

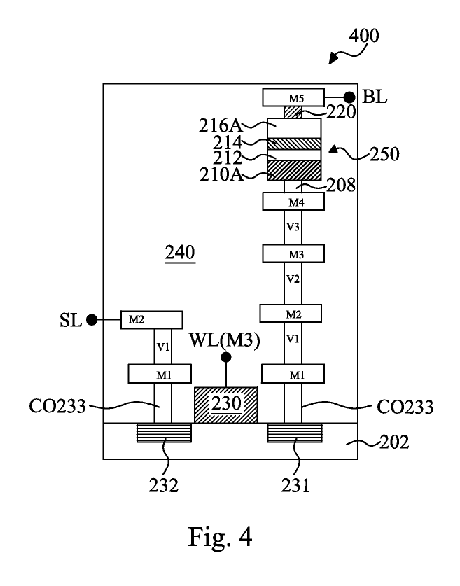

FIG. 4 shows a cross-sectional view of a semiconductor structure 400 with the resistance variable memory structure 250 of FIG. 2E according to one or more embodiments of the present disclosure. The semiconductor structure 400 may be formed on a bulk substrate 202 such as silicon, germanium, and/or a compound semiconductor material. The semiconductor structure 400 may include an access transistor that includes as a gate electrode 230, a drain region 231 and a source region 232 on opposite sides of the gate electrode 230. The gate electrode 230 is formed on a top surface of the bulk substrate 202. The source region 232 and the drain region 231 are formed by implantation in a portion of the bulk substrate 202. Multiple dielectric layers 240 are formed over the access transistor and the bulk substrate 202. According to one or more embodiments, multiple dielectric layers 240 comprises silicon oxide, FSG, PSG, BPSG, carbon doped silicon oxide, silicon nitride, silicon oxynitride, TEOS oxide, Black Diamond, amorphous fluorinated carbon, low-k dielectric material, or combinations thereof.

Referring still to FIG. 4, a plurality of stacked metallization layers and via layers are formed over the access transistor and embedded in the dielectric layers 240. In at least one embodiment, the plurality of metallization layers includes five metal layers M1 to M5. Vertical columnar vias (CO233, V1 to V3, 208 and 220) interconnect the source region 232 and the drain region 231 to metallization layer M1, and every two metallization layers M1 to M5. The plurality of stacked metal features and via layers provides interconnections between devices structures, circuits and inputs/outputs. The metallization layers and via layers may include aluminum, aluminum alloy, copper, copper alloy, titanium, titanium nitride, tantalum, tantalum nitride, tungsten, metal silicide, or combinations thereof.

In some embodiments, there are at least three metallization layers overlying the access transistor and underlying the resistance variable memory structure 250. In this illustrated example, the resistance variable memory structure 250 is formed between metallization layers M4 and M5. Vertical columnar vias 208 and 220 electrically connect the resistance variable memory structure 250 to the metallization layers M4 and M5, respectively. The source region 232 of the access transistor is coupled to a source line in metallization layer M2 through columnar via CO233, metallization layer M1 and columnar via V1. A word line in metallization layer M3 is electrically coupled the gate electrode 230 to provide a gate voltage to turn on the access transistor. The drain region 231 may be coupled to the first electrode 210A of the resistance variable memory structure 250 through columnar vias (CO233, V1 to V3 and 208) and metallization layer (M1 to M4). A bit line in metallization layer M5 is electrically coupled to the second electrode 216A of the resistance variable memory structure 250 through the columnar via 220.

Generally, the processes underlying bottom metallization layers (M1 to M3) may use a process temperature higher than 400° C. for annealing or dielectric layer formation in semiconductor structure 400 construction. The stability of a resistance variable memory structure 250 may be affected by the high temperature processes if the resistance variable memory structure 250 is formed before the high temperature processes. In this disclosure, the resistance variable memory structure 250 is formed over the bottom metallization layers (M1 to M3). This disclosure eliminates the drawbacks of high temperature effect on the resistance variable memory structure 250 in bottom metallization layers (M1 to M3). Furthermore, there are several control lines (such as the source line, the word line and the bit line) used to control the operation of the resistance variable memory structure 250 and the access transistor. There are many spaces needed in bottom metallization layers for circuit routing to arrange these control lines. Advantageously, the resistance variable memory structure 250 is formed over the bottom metallization layers (M1 to M3). In this illustrated example, the resistance variable memory structure 250 is formed between upper metallization layers M4 and M5. In accordance with one or more embodiments of the present disclosure, there are more spaces for circuit routing by forming the resistance variable memory structure 250 in the upper metallization layers.

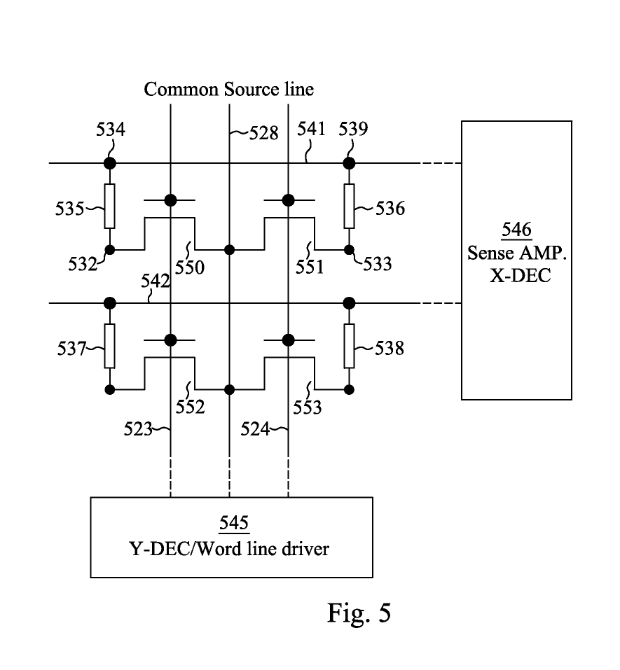

FIG. 5 is a schematic illustration of a memory array having resistance variable memory structures 535 to 538 according to at least one embodiment of this disclosure. The resistance variable memory structures 535 to 538 have a same structure 250 in FIG. 2E. In a schematic illustration of FIG. 5, a common source line 528, word lines 523 and 524 are arranged generally parallel in the Y-direction. Bit lines 541 and 542 are arranged generally parallel in the X-direction. Thus, a Y-decoder and a word line driver in block 545 are coupled to the word lines 523, 524. An X-decoder and set of sense amplifiers in block 546 are coupled to the bit lines 541 and 542. The common source line 528 is coupled to source terminals of access transistors 550, 551, 552 and 553. A gate electrode of access transistor 550 and a gate electrode of access transistor 552 are coupled to the word line 523, respectively. A gate electrode of access transistor 551 and a gate electrode of access transistor 553 are coupled to the word line 524, respectively. A drain of access transistor 550 is coupled to a first electrode 532 for the resistance variable memory structure 535, which is in turn coupled to second electrode 534. Likewise, a drain of access transistor 551 is coupled to a first electrode 533 for the resistance variable memory structure 536, which is in turn coupled to a second electrode 539. The second electrode 534 and the second electrode 539 are coupled to the same bit line 541. Access transistors 552 and 553 are coupled to corresponding resistance variable memory structures 537 and 538 as well on bit line 542. It can be seen that the common source line 528 is shared by two rows of resistance variable memory structures, where a row is arranged in the Y-direction in the illustrated schematic.

Various embodiments of the present disclosure may be used to improve the performance of a resistance variable memory structure. For example, the second metal material in the second electrode layer 216 is different from the first metal material in the cap layer 216. This disclosure eliminates the drawbacks of easily intermix of the second electrode layer 216 and the cap layer 214. This disclosure could reduce the operation voltage to generate the conduction portion in the resistance variable layer 212. The resistance variable memory structure could be operated at a lower voltage and the power is saved.

One aspect of the disclosure describes a semiconductor structure. The semiconductor structure includes a conductive structure. A resistance variable memory structure is over the conductive structure. The resistance variable memory structure includes a first electrode over the conductive structure. A resistance variable layer is disposed over the first electrode. A cap layer is disposed over the resistance variable layer. The cap layer includes a first metal material. A second electrode disposed over the cap layer. The second electrode includes a second metal material different from the first metal material.

A further aspect of the disclosure describes a semiconductor structure. The semiconductor structure includes a first access transistor including a first source region and a first drain region on opposite sides of a first gate electrode. A first resistance variable memory structure is over the first access transistor. The first resistance variable memory structure includes a first electrode disposed over the first access transistor and electrically connected to the first drain region. A first resistance variable layer is disposed over the first electrode. A first cap layer is disposed over the first resistance variable layer, the first cap layer comprising a first metal material comprising titanium. A second electrode is disposed over the first cap layer. The second electrode includes a second metal material different from the first metal material. The second metal material includes tantalum nitride.

The present disclosure also describes an aspect of a method of forming a semiconductor structure. The method includes forming a conductive structure in a top portion of a substrate. A first electrode layer is deposited over the conductive structure. A resistance variable layer is deposited over the first electrode layer. A cap layer is deposited over the resistance variable layer. The cap layer includes a first metal material. A second electrode layer is deposited over the cap layer. The second electrode layer includes a second metal material different from the first metal material. The second electrode layer, the cap layer, the resistance variable layer and the first electrode layer are etched to form a resistance variable memory structure.

Although the embodiments and its advantages have been described in detail, it should be understood that various changes, substitutions and alterations can be made herein without departing from the spirit and scope of the invention as defined by the appended claims. As one of ordinary skill in the art will readily appreciate from the present disclosure, processes, machines, manufacture, compositions of matter, means, methods, or steps that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor structure comprising:
a conductive structure; and
a resistance variable memory structure over the conductive structure, the resistance variable memory structure comprising:
a first electrode disposed over the conductive structure;
a resistance variable layer disposed over the first electrode;
a cap layer disposed over the resistance variable layer, the cap layer comprising a first metal material; and
a second electrode disposed over the cap layer, the second electrode comprising a second metal material different from the first metal material;
wherein the first electrode, the resistance variable layer, the cap layer, and the second electrode have aligned sidewalls.

2. The semiconductor structure of claim 1, wherein the cap layer comprises titanium, platinum or palladium.

3. The semiconductor structure of claim 1, wherein each of the first electrode and the second electrode comprises at least one of platinum, aluminum copper, titanium nitride, gold, titanium, tantalum, tantalum nitride, tungsten, tungsten nitride or copper.

4. The semiconductor structure of claim 1, wherein the second electrode comprises tantalum nitride.

5. The semiconductor structure of claim 1, wherein the resistance variable layer comprises at least one of a high-k dielectric material, a binary metal oxide or a transition metal oxide.

6. The semiconductor structure of claim 1, wherein the resistance variable layer comprises at least one of nickel oxide, titanium oxide, hafnium oxide, zirconium oxide, zinc oxide, tungsten oxide, aluminum oxide, tantalum oxide, molybdenum oxide or copper oxide.

7. The semiconductor structure of claim 1 further comprising an access transistor underlying the resistance variable memory structure, wherein the access transistor comprises a source region and a drain region.

8. The semiconductor structure of claim 7, wherein the first electrode of the resistance variable memory structure is electrically connected to the drain region of the access transistor.

9. The semiconductor structure of claim 1 further comprising at least three metallization layers underlying the conductive structure.

10. A semiconductor structure comprising:
a first access transistor comprising a first source region and a first drain region on opposite sides of a first gate electrode; and
a first resistance variable memory structure over the first access transistor, the first resistance variable memory structure comprising;
a first electrode disposed over the first access transistor and electrically connected to the first drain region;
a first resistance variable layer disposed over the first electrode, wherein the resistance variable layer includes at least one conductive filament;
a first cap layer disposed over the first resistance variable layer, the first cap layer comprising a first metal material comprising titanium; and
a second electrode disposed over the first cap layer, the second electrode comprising a second metal material different from the first metal material, wherein the second metal material comprises tantalum nitride.

11. The semiconductor structure of claim 10, wherein the first resistance variable layer comprises at least one of a high-k dielectric material, a binary metal oxide or a transition metal oxide.

12. The semiconductor structure of claim 10, wherein first the resistance variable layer comprises at least one of nickel oxide, titanium oxide, hafnium oxide, zirconium oxide, zinc oxide, tungsten oxide, aluminum oxide, tantalum oxide, molybdenum oxide or copper oxide.

13. The semiconductor structure of claim 11 further comprising at least three metallization layers overlying the first access transistor and underlying the first resistance variable memory structure.

14. The semiconductor structure of claim 11 further comprising:
a second access transistor comprising a second source region and a second drain region on opposite side of a second gate electrode;
a second resistance variable memory structure over the second access transistor;
a common source line coupled to the first source region and the second source region of the first access transistor and the second access transistor respectively; and
a common word line coupled to the first gate electrode and the second gate electrode of the first access transistor and the second access transistor respectively.

15. The semiconductor structure of claim 14, wherein the second resistance variable memory structure comprising:
a third electrode disposed over the second access transistor and electrically connected to the second drain region;
a second resistance variable layer disposed over the third electrode;
a second cap layer disposed over the second resistance variable layer, the second cap layer comprising the first metal material comprising titanium; and
a fourth electrode disposed over the second cap layer, the fourth electrode comprising the second metal material different from the first metal material, wherein the second metal material comprises tantalum nitride.

16. A method of forming a semiconductor structure, the method comprising:
forming a conductive structure in a top portion of a substrate;
depositing a first electrode layer over the conductive structure;
depositing a resistance variable layer over the first electrode layer, wherein the resistance variable layer includes at least one conductive filament;
depositing a cap layer over the resistance variable layer, the cap layer comprising a first metal material;
depositing a second electrode layer over the cap layer, the second electrode layer comprising a second metal material different from the first metal material; and
etching the second electrode layer, the cap layer, the resistance variable layer and the first electrode layer to form a resistance variable memory structure.

17. The method of claim 16, wherein the cap layer comprises at least one of titanium, platinum or palladium.

18. The method of claim 16, wherein the second electrode comprises tantalum nitride.

19. The method of claim 16, wherein the resistance variable layer comprises at least one of a high-k dielectric material, a binary metal oxide or a transition metal oxide.

20. The method of claim 16 further comprising forming at least three metallization layers underlying the resistance variable memory structure.
